(19) United States
(12) Patent Application Publication
(10) Pub. No.: US 2013/0316092 A1
(43) Pub. Date: Nov. 28, 2013

(54) METHOD OF HIGH RESOLUTION LASER ETCHING ON TRANSPARENT CONDUCTING LAYER OF TOUCH PANEL

(71) Applicant: TECO NANOTECH CO., LTD., Taoyuan County (TW)

(72) Inventors: Yao-Zong CHEN, Taoyuan County (TW); Yu-Yang CHANG, Taoyuan County (TW)

(73) Assignee: TECO NANOTECH CO., LTD., Taoyuan County (TW)

(21) Appl. No.: 13/666,873

(22) Filed: Nov. 1, 2012

(30) Foreign Application Priority Data
May 22, 2012 (TW) TW101118173

(51) Int. Cl. H05K 3/02; B82Y 99/00

(52) U.S. Cl. 427/555; 977/932

(57) ABSTRACT

The method disclosed comprises steps of preparing a transparent conducting material, and forming a transparent conducting ink with the transparent conducting material mixing with carbon materials. Next, prepare a transparent plastic film, and form a transparent conducting layer by forming the transparent conducting ink film on the transparent plastic film via spray coating, screen printing, ink jet printing or roll to roll ink coating film. Lastly, project laser beams on the transparent conducting layer of the transparent plastic film. The transparent conducting layer includes carbon materials for facilitating the light condensing effect of the laser beams. In the laser beams etching process, the line width of the transparent conducting layer etching is produced less than 50 um, the width of the ineffective area near the etching edge after the etching of the transparent conducting layer is less than 10 um in order to complete a high resolution laser etching process.

This application is based on and claims the benefit of Taiwan Application No. 101118173 filed May 22, 2012 the entire disclosure of which is incorporated by reference herein.

### BACKGROUND OF THE INVENTION

1. Field of the Invention

The present invention relates to a touch panel, in particularly to a laser processing machine and a laser etching method for producing transparent conducting layer patterns on transparent conducting layer of the touch panel.

2. Description of Prior Art

With the development of the technologies, various electronic devices are launched, where many electronic devices are equipped with touch panels for users' convenience to input instructions and texts. Users use stylus pen or fingers to stimulate the specific areas on a touch panel for issue instructions. Or, users may write texts on a touch panel. When a touch panel is equipped with a display screen, users may draw patterns on the touch panel. As a result of multiple input methods of a touch panel, touch panels are widely used in electronic devices. When a user stimulates a touch panel, electronic responses generated on the touch panel are used for sensing the coordinates of stimulated location and performing the tasks coordinating to the coordinates. Therefore, it is desired in the industry to research and develop means for precisely sensing the coordinates of the stimulated location by a user and minimizing the effects interfering with the electronic responses when the touch panel is stimulated.

In the example of a capacitive touch panel, when a user finger or a conductor touches the touch panel, the capacitive effect generated simultaneously, the changes of the capacitive values are used for determining the location of the fingers or the conductor and further perform corresponding input tasks. The substrate of a traditional capacitive touch panel is installed with positive and negative transparent conducting layers and conducting electrode lines. The working mechanism is when a user touches the transparent conducting layer between the negative and positive sensing electrodes, the finer provide a conductive path for the two sensing electrodes. The nerves or muscles are stimulated by the electric power and provide electronic stimulation tactile feedback, the location of the finger is determined and further the coordinates of the touch point by the finger on the touch panel is determined by measuring the capacitive value changes of the touch point of the transparent conducting layer between positive and negative electrodes and process the capacitive value changes with a touch control IC.

In related arts, there are many methods for performing etched pattern on transparent conducting layer of touch control board, for example using laser etching for performing etched pattern on the transparent sensing areas of the transparent conducting layer. Nonetheless, as the operation complexity increases, the demand on etching precision on the transparent sensing area of the positive and negative electrodes of the transparent conducting layer increases accordingly.

Because the transmittance of the transparent sensing conducting layer in the touch control board is higher than 85%. The conductive materials used in the structures are inorganic metal oxides such as ITO (Indium Tin Oxide) etc. The materials have a metallic luster. During laser etching, the laser beams are difficult to condense when projecting on the inorganic metal oxides, the range of etched width is at least above 70 um. Further, the ineffective area (the partially firing oxidized area by laser scattering) generated by laser etching on the conducting layer non-etched areas is above 50 um. As a result, the required etching area reserved in the designs has to be at least above 70 um, and the ineffective area around the pattern after the pattern etching on transparent conducting layer has to be at least 50 um.

### SUMMARY OF THE INVENTION

Therefore, the objective of the present invention is to overcome the disadvantages in the related arts. According to the present invention, the transparent conducting materials used for producing touch panels are added with carbon materials. The carbon materials are black materials, which provide light condensing effects of laser beam source. When etching with the light condensing laser beams, the etched line width of transparent conducting layer is less than 50 um, the width of the ineffective area near the etching edge after the etching of the transparent conducting layer can be less than 10 um. Thus, a transparent conducting layer of the positive and negative electrodes sensing with high resolution is generated via the above techniques.

In order to achieve the above objective, the present invention provides a method of high resolution laser etching on a transparent conducting layer of a touch panel for performing etching on a touch panel with a laser processing machine. The method comprises steps of:

preparing a transparent conducting material;

forming a transparent conducting ink with the transparent conducting material mixing with carbon materials;

preparing a transparent plastic film;

forming the transparent conducting ink film on the transparent plastic film for forming a transparent conducting layer;

projecting laser beams on the transparent conducting layer of the transparent plastic film, the transparent conducting layer including carbon materials for condensing the laser beams, for making the transparent conducting layer into the transparent conducting electrode with laser etching.

wherein, the transparent conducting material is an organic conducting paste of transparent conducting resin.

wherein, the carbon material is carbon powder, graphite, active carbon, carbon fiber, Graphene or Carbon Nanotube.

wherein, the transparent plastic film is polyethylene terephthalate.

wherein, the transparent conducting layer is film formed on the transparent plastic film by spray coating, screen printing, ink jet printing or roll to roll ink coating.

wherein, the carbon material content of the transparent conducting layer is 0.001%˜0.1%.

wherein, the transparent conducting layer has 0.001%˜0.1% content of the carbon material, and is controlled by the repetitive of spray coating, screen printing, ink jet printing or roll to roll ink coating.

wherein, the carbon material usage quantity is 0.05%.

wherein, the laser wavelength of the laser processing machine is 1064 nm, power is 3±1 W, and pulse frequency is 80 KHz.

wherein, the line width of transparent conducting electrode after the etching of the transparent conducting layer is less than 50 um.

wherein, the width of the ineffective area near the etched edge after the etching process of the transparent conducting layer is less than 10 um.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1 is a schematic manufacturing flowchart of the touch panel according to the present invention;

FIG. 2 is a side schematic view of the touch panel according to the present invention;

FIG. 3 is a top schematic view of the touch panel according to the present invention; and

FIG. 3A is an enlarged schematic view of the touch panel according to the present invention.

### DETAILED DESCRIPTION OF THE INVENTION

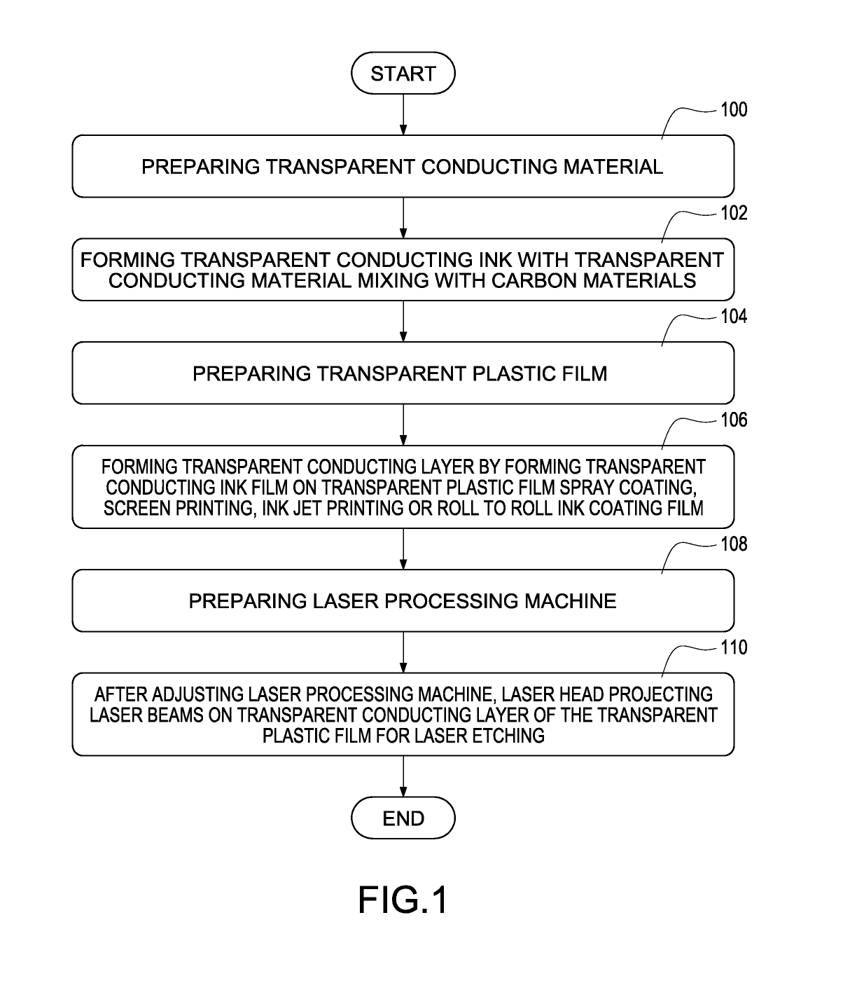

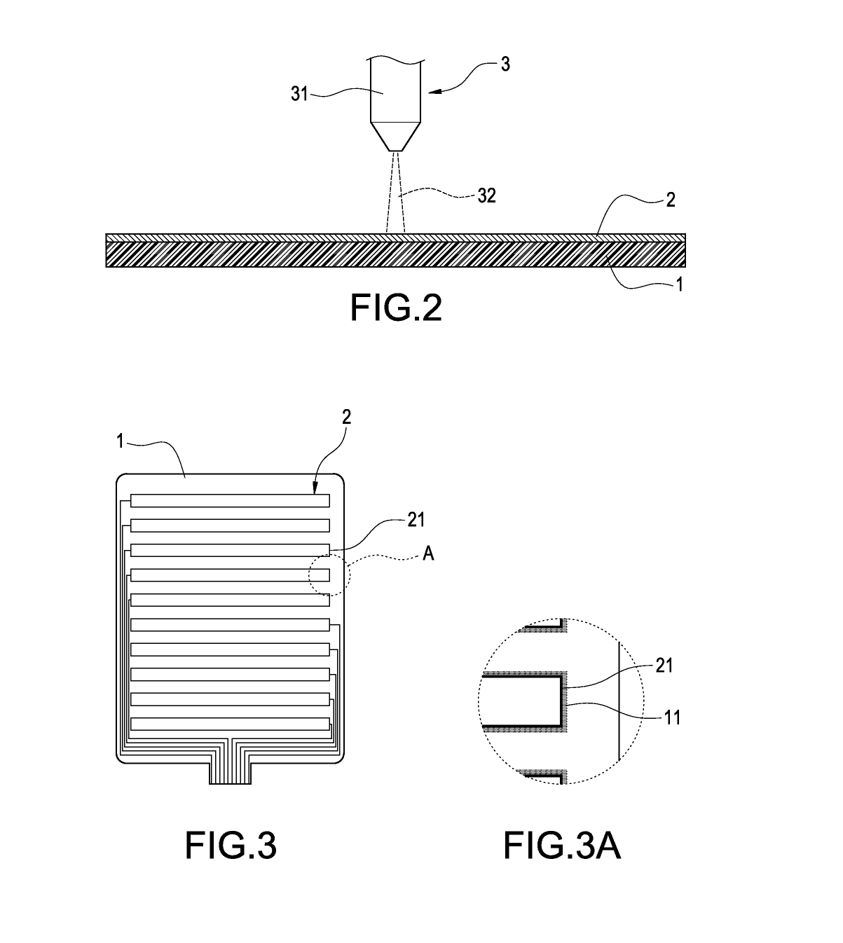

FIG. 1, FIG. 2 and FIG. 3 are a schematic manufacturing flowchart, side schematic view, and top schematic view of the touch panel according to the present invention. According to the diagrams, the method of high resolution laser etching on a transparent conducting layer of a touch panel starts with the step 100: preparing a transparent conducting material. In the diagram, the conducting material is organic conducting paste of transparent conducting resin.

Step 102 is forming a transparent conducting ink with the transparent conducting material mixing with carbon materials. In the diagram, the carbon materials are carbon powders, graphite, active carbon, carbon fiber, Graphene or Carbon Nanotube.

Step 104 is preparing a transparent plastic film 1, the transparent plastic film 1 is PET plastic film (polyethylene terephthalate).

Step 106 is forming a transparent conducting layer 2 by forming the transparent conducting ink film on the transparent plastic film 1 via spray coating, screen printing, ink jet printing or roll to roll ink coating film. The carbon material content of the transparent conducting layer 2 is 0.001%˜0.1% (the optimized powder usage quantity is 0.05%).

Step 108 is preparing a laser processing machine 3, and adjusting the laser wavelength of the laser processing machine 3 as 1064 nm, power is 3±1 W, and the pulse frequency as 80 KHz.

Step 110 is that the laser head 31 projecting the laser beams 32 on the transparent conducting layer 2 of the transparent plastic film 1 after the laser processing machine 3 is adjusted. The transparent conducting layer 2 includes the carbon material content. The carbon materials are black. Accordingly, when the laser beams 32 are focused on the transparent conducting layer 2, light condensing effect of the laser beams 32 focus on the transparent conducting layer 2 is desirable. When the laser beams 32 perform etching, the line width of the transparent conducting electrode 21 etched on the transparent conducting layer 2 is less than 50 um, and the width of the ineffective area 11 near the etching edge is less than 10 um (as shown in FIG. 3 and FIG. 3A) after the etching of the transparent conducting layer 2.

According to the present invention, carbon materials such as Carbon Nanotube powders are added to the transparent conducting material. In contrast with the traditional transparent conducting material without adding the carbon materials, the differences of the line width of transparent conducting electrode on the transparent conducting layers after laser beams etching are listed in the following:

The embodiment cased on related art:

The content of carbon material: 0%

The transparent conducting material: ITO

The transparent substrate: PET

The repetitive times of spray coating: 0 times

The transmittance: 85%

The surface resistance: 450Ω/□

The minimum line width after laser etched: >70 um

The width of ineffective area: >50 um

In a traditional touch panel, the transparent conducting material is sputtered on the transparent plastic film PET to assure the transmittance is above 85%, the surface resistance measured is 450Ω/□. However, the transparent conducting material is not added with the carbon materials. During the laser etching, the laser beams diffused easily and the energy condensing effect of the laser beams is inferior. Accordingly, the minimum line width after laser etching is above 70 um, and width of the ineffective area is also above 50 um.

### EMBODIMENTS BASED ON THE PRESENT INVENTION

### The First Embodiment

The content of carbon material: 0.001%˜0.01% Carbon Nanotubes

The transparent conducting material: organic conducting paste

The transparent substrate: PET

The repetitive times of spray coating: 10 times

The transmittance: >90%

The surface resistance: 800Ω/□

The minimum line width after laser etched: <45 um

The width of ineffective area: <10 um

In the touch panel in the first embodiment of the present invention, the transparent conducting material is organic conducting paste, and the organic conducting paste is added with 0.001%˜0.01% Carbon Nanotube. After forming the transparent conducting ink, the transparent conducting layer is formed by spray coating the transparent conducting ink on the transparent substrate PET. The transmittance of the transparent conducting layer is above 90%, and the surface resistance measured is 800Ω/□. During the laser etching, the energy condensing effect of the laser beams is desirable. Accordingly, the minimum line width after laser etched is below 45 um, and width of the ineffective area is also below 10 um.

### The Second Embodiment

The content of carbon material: 0.001%˜0.01% Carbon Nanotubes

The transparent conducting material: organic conducting paste

The transparent substrate: PET

The repetitive times of spray coating: 20 times

The transmittance: >88%

The surface resistance: 400Ω/□

The minimum line width after laser etched: <40 um

The width of ineffective area: <10 um

In the touch panel in the second embodiment of the present invention, the transparent conducting material is organic conducting paste, the organic conducting paste is added with 0.001%˜0.01% Carbon Nanotubes. After the transparent conducting ink is formed, the transparent conducting layer is formed by spray coating the transparent conducting ink on the transparent substrate PET. The transmittance of the transparent conducting layer is above 88%, the surface resistance measured is 400Ω/□. During laser etching, the energy condensing effect of the laser beams is desirable. Accordingly, the minimum line width after laser etched is below 40 um, and the width of the ineffective area is also below 10 um.

### Third Embodiment

The content of carbon material: 0.001%˜0.01% Carbon Nanotubes

The transparent conducting material: organic conducting paste

The transparent substrate: PET

The repetitive times of spray coating: 40 times

The transmittance: >85%

The surface resistance: 200Ω/□

The minimum line width after laser etched: <35 um

The width of ineffective area: <10 um

In the touch panel in the third embodiment of the present invention, the transparent conducting material is organic conducting paste, the organic conducting paste is added with 0.001%˜0.01% Carbon Nanotubes. After the transparent conducting ink is formed, the transparent conducting layer is formed by spray coating the transparent conducting ink on the transparent substrate PET. The transmittance of the transparent conducting layer is above 85%, the surface resistance measured is 200Ω/□. During laser etching, the energy condensing effect of the laser beams is desirable. Accordingly, the minimum line width after laser etched is below 35 um, and the width of the ineffective area is also below 10 um.

### Fourth Embodiment

The content of carbon material: 0.001%˜0.01% carbon powder

The transparent conducting material: organic conducting paste

The transparent substrate: PET

The repetitive times of spray coating: 50 times

The transmittance: >85%

The surface resistance: 700Ω/□

The minimum line width after laser etched: <50 um

The width of ineffective area: <10 um

In the touch panel in the fourth embodiment of the present invention, the transparent conducting material is organic conducting paste, the organic conducting paste is added with 0.001%˜0.01% carbon powder. After the transparent conducting ink is formed, the transparent conducting layer is formed by spray coating the transparent conducting ink on the transparent substrate PET. The transmittance of the transparent conducting layer is above 85%, the surface resistance measured is 700Ω/□. During laser etching, the energy condensing effect of the laser beams is desirable. Accordingly, the minimum line width after laser etched is below 50 um, and the width of the ineffective area is also below 10 um.

Comparing the first to the fourth embodiments with the traditional embodiment, it is apparent that combining transparent conducting layers with carbon materials added along with etching based on the adjustment configuration of laser beams output according to the present invention results in excellent etched line widths. The resulted line width of a transparent conducting circuit is below 50 um. In addition, the width of the ineffective area near the etching edge is below 10 um in the first to fourth embodiments. On the other hand, the width of the ineffective area near the etching edge of the traditional embodiment is at least above 50 um. In the first to third embodiments, as the content of the added carbon increases in the transparent conducting layer, the energy condensing effect of the laser beams generated by the laser processing machine improves, and the etched line width decreases as the usage quantity of the carbon materials increases. Furthermore, the fourth embodiment shows adding carbon powders also deliver the same desirable result.

Additionally, according to the present invention, the 0.001%˜0.1% carbon material content, which is formed on the transparent plastic film of the transparent conducting layer via spray coating or sputtering, is controlled by the thickness of the transparent conducting layer formed by spray coating, screen printing, ink jet printing or roll to roll ink coating.

As the skilled person will appreciate, various changes and modifications can be made to the described embodiments. It is intended to include all such variations, modifications and equivalents, which fall within the scope of the invention, as defined in the accompanying claims.

What is claimed is:

1. A method of high resolution laser etching on a transparent conducting layer of a touch panel, for a processing machine to perform etching on a touch panel, the method comprising:
a). preparing a transparent conducting material;
b). forming a transparent conducting ink with the transparent conducting material mixing with carbon materials;
c). preparing a transparent plastic film;
d). forming the transparent conducting ink film on the transparent plastic film for forming a transparent conducting layer;
e). projecting laser beams on the transparent conducting layer of the transparent plastic film, the transparent conducting layer including carbon materials for condensing the laser beams, for making the transparent conducting layer into a transparent conducting electrode with laser etching.

2. The method of high resolution laser etching of claim 1, wherein, the transparent conducting material in the step a is an organic conducting paste made of transparent conducting resin.

3. The method of high resolution laser etching of claim 2, wherein, the carbon material in the step b is carbon powder, graphite, active carbon, carbon fiber, Graphene or Carbon Nanotubes.

4. The method of high resolution laser etching of claim 3, wherein, the transparent plastic film in the c step is polyethylene terephthalate.

5. The method of high resolution laser etching of claim 4, wherein, the transparent conducting layer in the step d is film formed on the transparent plastic film by spray coating, screen printing, ink jet printing or roll to roll ink coating.

6. The method of high resolution laser etching of claim 5, wherein, the carbon material content of the transparent conducting layer in the d step is 0.001%˜0.1%.

7. The method of high resolution laser etching of claim 6, wherein, the transparent conducting layer has 0.001%˜0.1% of the carbon material, and is controlled by the repetitive of spray coating, screen printing, ink jet printing or roll to roll ink coating.

8. The method of high resolution laser etching of claim 7, wherein, the carbon material usage quantity is 0.05%.

9. The method of high resolution laser etching of claim 8, wherein, the laser wavelength of the laser processing machine in the e step is 1064 nm, power is 3±1 W, and pulse frequency is 80 KHz.

10. The method of high resolution laser etching of claim 9, wherein, the line width of transparent conducting electrode after etched of the transparent conducting layer is less than 50 um.

11. The method of high resolution laser etching of claim 10, wherein, the width of the ineffective area near the etching edge after etched of the transparent conducting layer is less than 10 um.
